(19) United States
(12) Patent Application Publication
(10) Pub. No.: US 2025/0392278 A1
(43) Pub. Date: Dec. 25, 2025

(54) SYSTEM AND METHOD FOR DIGITAL SIGNAL PROCESSING USING ADAPTIVE SOFT CLIPPING WITH LOOKAHEAD

(71) Applicant: Immersion Networks, Inc., Redmond, WA (US)

(72) Inventor: Serge SMIRNOV, Redmond, WA (US)

(73) Assignee: Immersion Networks, Inc., Redmond, WA (US)

(21) Appl. No.: 18/878,265

(22) PCT Filed: Jun. 20, 2023
(86) PCT No.: PCT/US2023/025723

§ 371 Date: Dec. 23, 2024

Related U.S. Application Data
(60) Provisional application No. 63/353,957, filed on Jun. 21, 2022.

(51) Int. Cl. H03G 11/00; H03G 5/16

(52) U.S. Cl. CPC H03G 11/008; H03G 5/16

(57) ABSTRACT

A system for processing an audio signal, comprising one or more algorithms operating on a processor and configured to generate a block of audio data, determine whether a previous block of audio data was processed with dipping active, scan the block of audio data to generate lookahead information if the previous block of audio data was not processed with clipping active and use adaptive soft clipping if the previous block of audio data was processed with clipping active.

### TECHNICAL FIELD

The present disclosure relates generally to digital audio signal processing, and more specifically to a system and method for digital signal processing using adaptive soft clipping with lookahead.

### BACKGROUND OF THE INVENTION

Clipping is a form of distortion to the waveform of a signal. It limits the signal within some range (e.g. [−1 . . . +1]) with minimal changes to small signals. One of the techniques is hard clipping that uses the simple operation min(1,max (x,−1)). Hard clipping is widely used in that it does not modify signals that don't need clipping. However, hard clipping may make clipped signal sound bad because of the sharp corners it forms. Soft clipping where the comers are smoothed may be used as another clipping technique.

### SUMMARY OF THE INVENTION

A system for processing an audio signal is disclosed that includes one or more algorithms operating on a processor that are configured to generate a block of audio data and to determine whether a previous block of audio data was processed with clipping active. The block of audio data is scanned to generate lookahead information if the previous block of audio data was not processed with clipping active, and adaptive soft clipping is used if the previous block of audio data was processed with clipping active.

Other systems, methods, features, and advantages of the present disclosure will be or become apparent to one with skill in the art upon examination of the following drawings and detailed description. It is intended that all such systems, methods, features and advantages be included within this description, be within the scope of the present disclosure, and be protected by the accompanying claims.

### BRIEF DESCRIPTION OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views.

FIG. 1 is a diagram illustrating exemplary clippings applied to a signal, according to the present disclosure.

FIG. 2 is a diagram illustrating exemplary input-output mappings for a signal, according to the present disclosure.

FIG. 3 is a diagram illustrating a low-threshold clipping on a small signal, according to the present disclosure.

FIG. 4 is a diagram illustrating an example implementation of processing a digital signal, according to the present disclosure.

FIG. 5 is a diagram illustrating an example clipping without lookahead, according to the present disclosure.

FIG. 6 is a diagram illustrating an example clipping without lookahead, according to the present disclosure.

FIG. 7 is a diagram illustrating the states information about clipping applied on the signal being processed, according to the present disclosure.

FIG. 8 is a diagram illustrating example implementations of clipping when lookahead is insufficient, according to the present disclosure.

FIG. 9 is a flow chart illustrating a method of processing a signal, according to the present disclosure.

FIG. 10 is a flow chart illustrating a method of processing a signal, according to the present disclosure.

FIG. 11 is a block diagram illustrating an example computer system 1100 that may be configured to implement various features of the present disclosure, according to the present disclosure.

### DETAILED DESCRIPTION OF THE INVENTION

Note that for simplicity, the present disclosure mainly discusses positive signals. In reality, negative signals have to be handled as well, where negative signals are treated symmetrically with respect to positive signals.

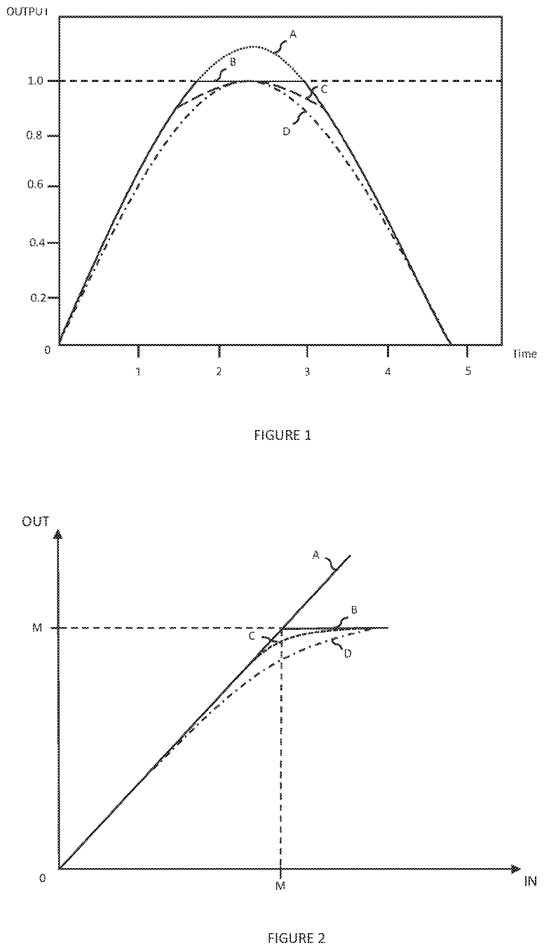

FIG. 1 is a diagram illustrating exemplary clippings applied to a signal, according to the present disclosure. The horizontal dashed line represents the maximum allowed output value. The maximum allowed output value in FIG. 1 is 1. The curved dashed line (A) represents the portion of the input signal exceeding that value. Curve B shows hard clipping (with a large straight flat section). The derivative discontinuities at the tips of the “cat's ears” in B are largely responsible for the bad sound of hard clipping.

Soft clipping avoids derivative discontinuities by applying a smooth curve that begins deviating from a straight line well below 1. Simple soft clipping is an input to output value mapping that works independently for each sample. Soft clipping examples are illustrated in FIG. 1. Curve C shows soft clipping with a relatively high threshold. Curve D shows soft clipping with a lower threshold.

FIG. 2 is a diagram illustrating exemplary input-output mappings for a signal, according to the present disclosure. FIG. 2 shows the input-output mapping for no clipping (A), hard clipping (B), and 2 possible curves for soft clipping (C and D). These letter labels match those in FIG. 1. M is the maximum allowed output value. Options C and D illustrate a tradeoff. Curve C has significant distortion near the clipping point because, although derivative discontinuities are avoided, the relatively quick derivative changes near the corners still causes some distortion. Curve D, by using larger rounding, reduces that distortion. But the early start of clipping (e.g. 0.5 for D in these diagrams) may affect smaller signals that don't need clipping at all.

FIG. 3 is a diagram illustrating a low-threshold clipping on a small signal, according to the present disclosure. FIG. 3 illustrates the tradeoff of Option D discussed in FIG. 2. The upper curve 302 is a small signal that does not require clipping since the signal does not exceed beyond a threshold M. The bottom curve 304 is the same signal reduced by a low-threshold soft clipping curve. By applying a low-threshold clipping, the smaller signals that don't need clipping at all are affected.

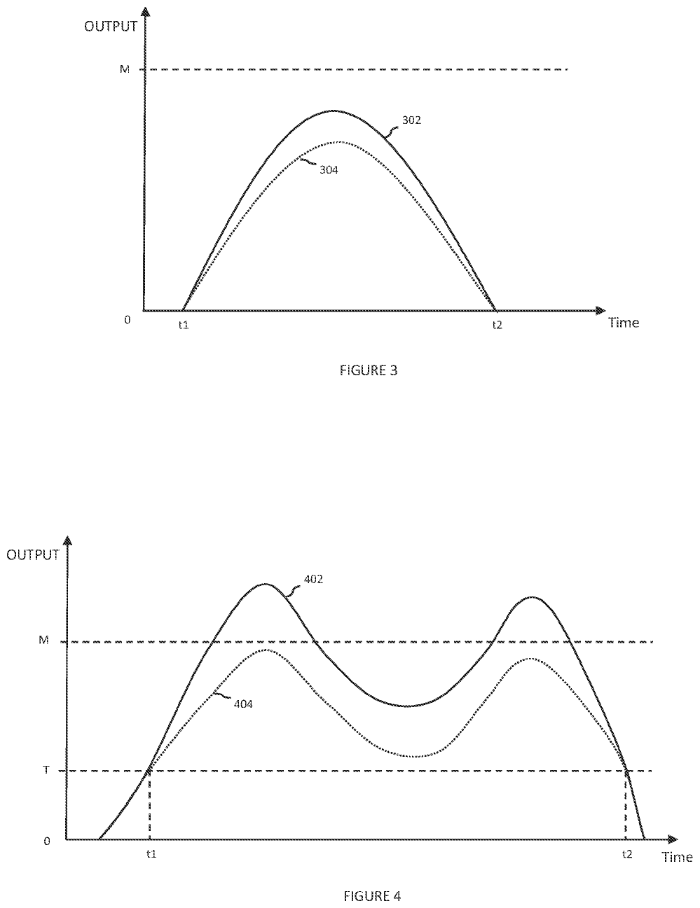

FIG. 4 is a diagram illustrating an example implementation of processing a digital signal, according to the present disclosure. Adaptive soft clipping is the idea of tuning the shape of the clipping curve to each section where clipping is needed and copying the input unaltered where clipping is not needed. M is the maximum allowed output value (e.g. 1). T is the threshold signal level where the clipping begins. Sample values smaller than T pass through unaltered. Samples values greater than T are altered if and only if clipping is needed. The approach is, for each sample that exceeds M, to trace the waveform forward and back until points on both sides are found where the signal drops below T.

The region between those points t1 and t2 is where a clipping curve is applied. The shape of that curve can be designed to be optimal for the signal in that range. The curve's most logical design constraints are that (1) its derivative at T is 1 (to maintain derivative continuity with the unprocessed portion of the signal outside the affected time range), and (2) the curve's output just reaches M for the largest input value within the time range. There are existing techniques to design such curves. For example, popular quadratic curves work as well in the present disclosure. The present disclosure is about the fact that a different curve is used for each time range where clipping is needed.

FIG. 5 is a diagram illustrating an example clipping without lookahead, according to the present disclosure. Lookahead is desired because the time range that requires consistent processing (as illustrated in FIG. 4, the region between points t1 and t2 where the signal drops below T) may span processing block boundaries in a streaming implementation. FIG. 5 shows what happens if the new block is being processed without lookahead information from the previous block. M is the maximum allowed output value (e.g. 1). T is the threshold signal level where the clipping begins. Consider a block boundary at t3 that separate the signal into two blocks (block t1-t3 and block t3-t2). Without lookahead, the portions before and after the block boundary are processed independently and soft clipping is applied to one block (block t3-t2 in the current example) but not the other, which would result in a discontinuity at the block boundary. As illustrated in FIG. 5, a signal processed before the block boundary (block t1-t3) would be passed through unaltered because clipping is not known when it would be needed when the signal is being processed. When the block after the boundary (block t3-t2) is being processed, the signal exceeding M is clipped, and a curve below M is applied. The signal is brought down lower (curve 504) and a discontinuity is caused at the block boundary. Soft clipping with lookahead can avoid the discontinuity at the block boundary.

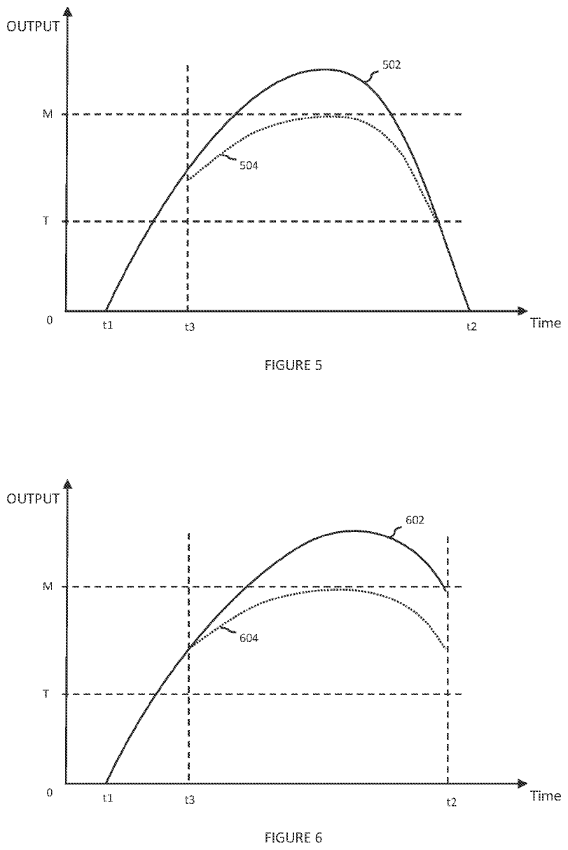

FIG. 6 is a diagram illustrating an example clipping without lookahead, according to the present disclosure. The vertical dashed line at t3 is a block boundary. M is the maximum allowed output value (e.g. 1). T is the threshold signal level where the clipping begins. Without lookahead, while processing the previous block, there is not enough information to determine whether soft clipping should be applied in the next block. The ambiguity caused by not being able to see passed the block boundary is illustrated in FIG. 6. Soft clipping with lookahead can avoid the ambiguity that whether or not its samples will ultimately need to be affected by soft-clipping curve to clip the signal in the next block.

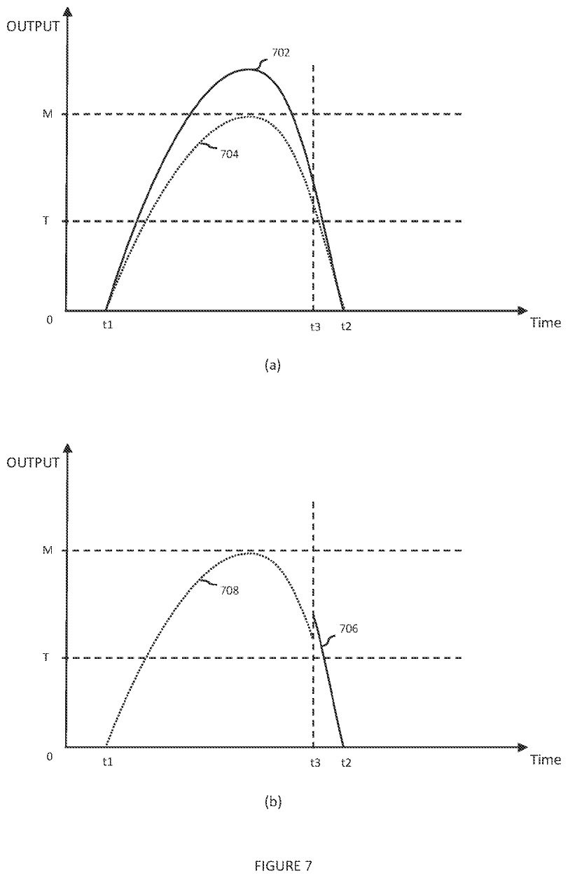

FIG. 7 is a diagram illustrating the states information about clipping applied on the signal being processed, according to the present disclosure. In addition to lookahead, state needs to be maintained about what clipping, if any, was being applied at the end of the previous block. M is the maximum allowed output value (e.g. 1). T is the threshold signal level where the clipping begins. FIG. 7(a) shows the input (curve 702) and intended output (curve 704). FIG. 7(b) is a diagram showing the discontinuity if states are not maintained across blocks. Specifically, an implementation must remember what clipping curve was applied at the end of the previous block, so that it can continue applying that same curve until the signal drops below T.

The implementation described so far works as long as the signal never spends more than “lookahead” time above T. If we assume the signal contains no energy below 20 Hz and can afford 25 ms of lookahead (half a period), that should suffice in theory. But a practical implementation ought to handle, without generating discontinuities, inputs that occasionally contain lower frequencies. For example, a poorly produced piece of content could have a DC offset, and if that DC offset exceeds T (0 is in fact a very reasonable choice of T), the waveform may spend a long period of time above T. Additionally, latency constraints might make 25 ms lookahead undesirable. For all these reasons, a practical implementation must have a backup plan for when lookahead is insufficient.

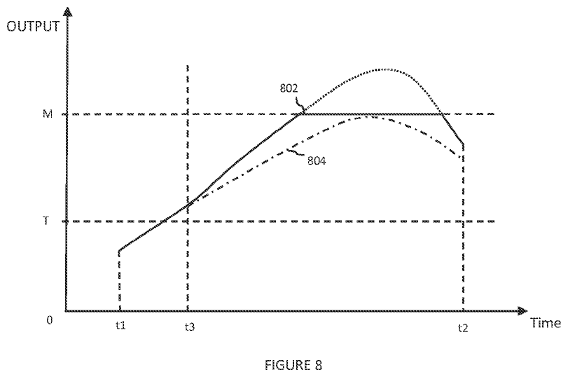

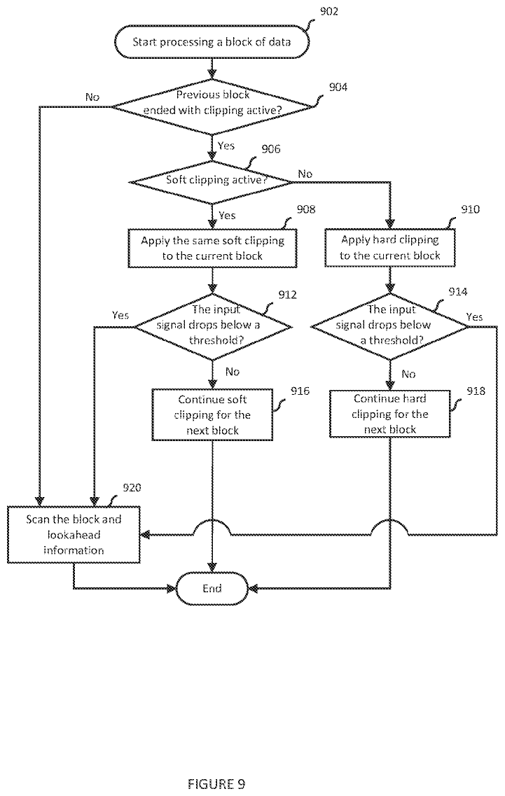

FIG. 8 is a diagram illustrating example implementations of clipping when lookahead is insufficient, according to the present disclosure. If lookahead is not sufficient, by the time soft clipping is determined needed, some of the samples that would be affected by soft clipping have already been outputted. There are two possible implementations dealing with insufficient lookahead. Consider a block boundary at t3 that separates the signal into two blocks (block t2-t3 and block t3-t2). Curve 802 can be generated by a hard clipping. Curve 804 can be generated by designing a special clipping curve whose value and derivative are both continuous with the end of the previous block (block t1-t3). The special soft clipping curve can use the value at the block boundary as its threshold.

FIG. 9 is a flow chart illustrating a method of processing a signal, according to the present disclosure. Note that the method is illustrating how positive values are handled. Negative values are handled in a similar way if they are not explicitly covered in the present disclosure. The method starts at processing a block of data 902. The method proceeds to step 904, whether the previous block ended with clipping active. If so, then the method further examines if it is soft clipping active 906; otherwise the method proceeds to step 920 scan the block and lookahead information. The method proceeds to step 908 if previous block ended with soft clipping active, then the same soft clipping curve is applied to the current block; otherwise the method proceeds to step 910 and hard clipping is applied to the current block. For soft clipping or hard clipping respectively, the method examines if the input signal drops below a threshold (steps 912 and 914). If so, the method proceeds to step 920; otherwise, respective clipping is applied for the next block (steps 916 and 918).

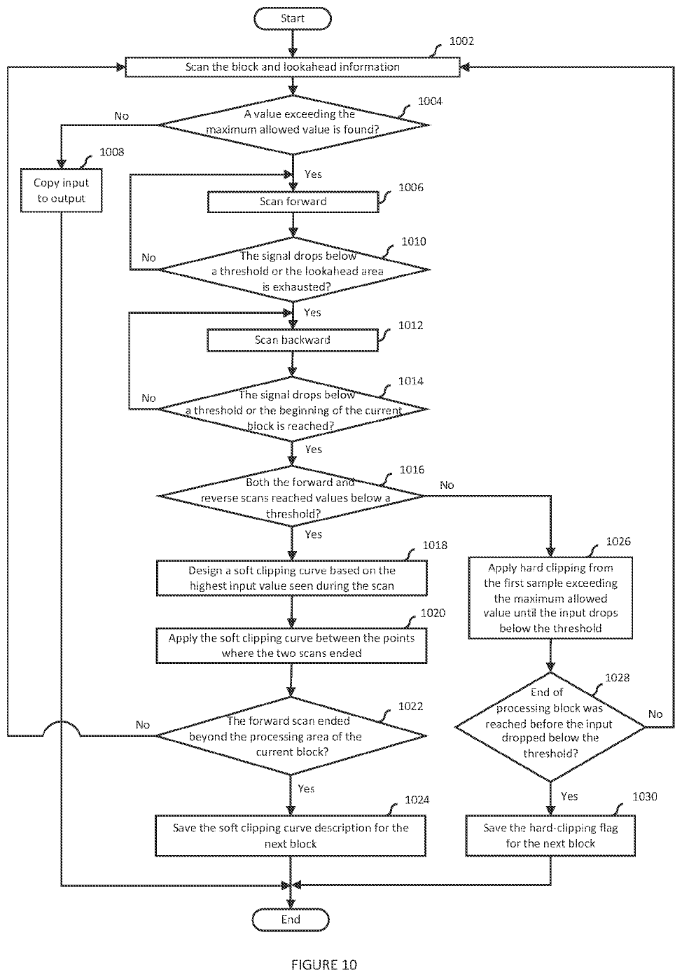

FIG. 10 is a flow chart illustrating a method of processing a signal, according to the present disclosure. The method starts with scanning the block and lookahead information at step 1002. The method proceeds to step 1004, whether a value exceeding the maximum allowed value is found. If so, the system scans forward at step 1006; otherwise, the method proceeds to 1008 where input is copied to output. The method further examines if the signal drops below the threshold or the lookahead area is exhausted at step 1010. If so, the method proceeds to step 1012 and scans backward; otherwise, the method repeats the step 1006 until signal drops below the threshold or the lookahead area is exhausted. The method further proceeds to step 1014, whether the signal drops below the threshold or the beginning of the current block is reached. If so, the method proceeds to step 1016, whether both the forward and reverse scans reached values below the threshold; otherwise, the method repeats the step 1012 until signal drops below the threshold or the beginning of the current block is reached. If both the forward and reverse scans reached values below the threshold, a soft clipping curve is designed based on the highest input value seen during the scan at step 1018 and the soft clipping curve is applied between the points where the two scans ended at step 1020; otherwise (for example, one of the two scans ran out of buffer), hard clipping is applied from the first sample exceeding the maximum allowed value until the input drops below the threshold at step 1026. In the case when soft clipping curve is applied, the methods examines whether the forward scan ended beyond the processing area of the current block at step 1022. If so, the soft clipping curve description is saved for the next block at step 1024; otherwise, the method repeats from step 1002. In the case when hard clipping is applied (step 1026), if end of processing block was reached before the input dropped below the threshold at step 1028, the hard-clipping flag is saved for the next block at step 1030; otherwise, the method repeats from step 1002.

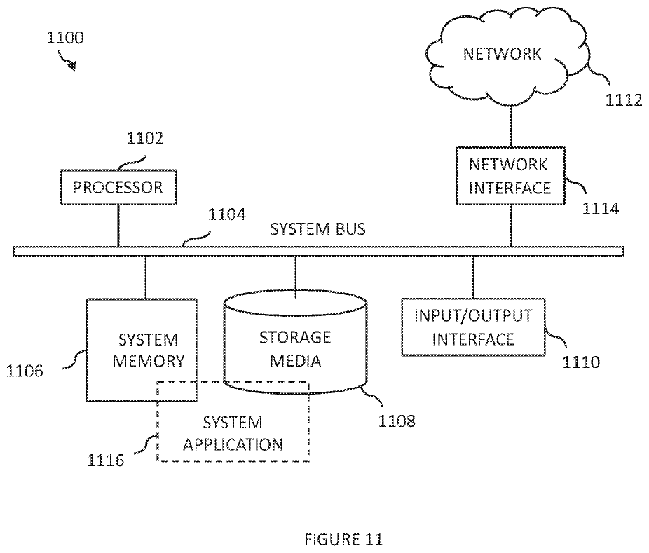

FIG. 11 is a block diagram illustrating an example computer system 1100 that may be configured to implement various features of the present disclosure according to the present disclosure. Embodiments of present disclosure can be implemented in hardware, or as a combination of software and hardware. Consequently, embodiments of the invention may be implemented in the environment of a computer system or other processing system. An example of such a computer system 1100 is shown in FIG. 11. Embodiments of the present disclosure can be implemented on one or more computer systems 1100. All of the steps of the flow charts depicted in FIGS. 9 and 10 can be implemented on one or more computer systems 1100.

Computer system 1100 can include various internal or attached components such as a processor 1102, system bus 1104, system memory 1106, storage media 1108, input/output interface 1110, and a network interface 1114 for communicating with a network 1112. A system application 1116 can operate in the system memory 1106 and storage media 1108. The computer system can include one or more processors 1102 that can be a special purpose or a general-purpose digital signal processor. The processor 1102 is connected to a system bus 1104.

The system memory 1106 can include non-volatile memories such as read-only memory (“ROM”), programmable read-only memory (“PROM”), erasable programmable read-only memory (“EPROM”), flash memory, or any other device capable of storing program instructions or data with or without applied power. The system memory 1106 can also include volatile memories such as random-access memory (“RAM”), static random-access memory (“SRAM”), dynamic random-access memory (“DRAM”), and synchronous dynamic random-access memory (“SDRAM”). Other types of RAM also can be used to implement the system memory 1106.

The storage media 1108 can store one or more operating systems, application programs and program modules. The storage media 1108 can be part of, or connected to, the computing machine 600. The storage media 1108 can also be part of one or more other computing machines that are in communication with computer system 1100 such as servers, database servers, cloud storage, network attached storage, and so forth.

The input/output (“I/O”) interface 1110 can be configured to couple to one or more external devices, to receive data from the one or more external devices, and to send data to the one or more external devices. The computer system 1100 can operate in a networked environment using logical connections through the network interface 1114 to one or more other systems or computing machines across the network 1112.

The system application 1116 can comprise one or more hardware or software hardware or software elements designed to facilitate the computer system 1100 in performing the various methods and processing functions presented herein. Furthermore, the system applications 1116 can comprise one or more sequences of instructions stored as software or firmware in association with the system memory 1106, the storage media 1108, or both. The storage media 1108 can therefore represent examples of machine or computer readable media on which instructions or code can be stored for execution by the processor 1102. Machine or computer readable media can generally refer to any medium or media used to provide instructions to the processor 1102. Such machine or computer readable media associated with system application 1116 can comprise a computer software product. It should be appreciated that a computer software product comprising system application 1116 can also be associated with one or more processes or methods for delivering the system application 1116 to the computer system 1100 via network interface 1114 any signal-bearing medium, or any other communication or delivery technology. The system application 1116 can also comprise hardware circuits or information for configuring hardware circuits such as microcode or configuration information for an FPGA or other PLD.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general-purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for processing an audio signal, comprising:
one or more algorithms operating on a processor and configured to:
generate a block of audio data;
determine whether a previous block of audio data was processed with clipping active;
scanning the block of audio data to generate lookahead information if the previous block of audio data was not processed with clipping active; and
using adaptive soft clipping if the previous block of audio data was processed with clipping active.

2. The system of claim 1 wherein using adaptive soft clipping if the previous block of audio data was processed with clipping active comprises using adaptive soft clipping with lookahead.

3. The system of claim 1 further comprising applying a same soft clipping to the block of audio data as was applied to the previous block of audio data.

4. The system of claim 1 further comprising applying a same soft clipping to the block of audio data as was applied to the previous block of audio data if it is determined that soft clipping is active.

5. The system of claim 1 further comprising applying hard clipping to the block of audio data.

6. The system of claim 1 further comprising applying hard clipping to the block of audio data if it is determined that soft clipping is not active.

7. The system of claim 1 further comprising determining whether an input signal has dropped below a threshold.

8. The system of claim 1 further comprising determining whether an input signal has dropped below a threshold and continuing soft clipping if the input signal has not dropped below the threshold.

9. The system of claim 1 further comprising determining whether an input signal has dropped below a threshold and continuing hard clipping if the input signal has not dropped below the threshold.

10. The system of claim 1 further comprising determining whether an input signal has dropped below a threshold and scanning the block of audio data to generate the lookahead information if the input signal has dropped below the threshold.

11. A method for processing an audio signal, comprising:
generating a block of audio data using one or more algorithms operating on a processor;
determining whether a previous block of audio data was processed with clipping active;
scanning the block of audio data to generate lookahead information if the previous block of audio data was not processed with clipping active; and
using adaptive soft clipping if the previous block of audio data was processed with clipping active.

12. The method of claim 11 wherein using adaptive soft clipping if the previous block of audio data was processed with clipping active comprises using adaptive soft clipping with lookahead.

13. The method of claim 11 further comprising applying a same soft clipping to the block of audio data as was applied to the previous block of audio data.

14. The method of claim 11 further comprising applying a same soft clipping to the block of audio data as was applied to the previous block of audio data if it is determined that soft clipping is active.

15. The method of claim 11 further comprising applying hard clipping to the block of audio data.

16. The method of claim 11 further comprising applying hard clipping to the block of audio data if it is determined that soft clipping is not active.

17. The method of claim 11 further comprising determining whether an input signal has dropped below a threshold.

18. The method of claim 11 further comprising determining whether an input signal has dropped below a threshold and continuing soft clipping if the input signal has not dropped below the threshold.

19. The method of claim 11 further comprising determining whether an input signal has dropped below a threshold and continuing hard clipping if the input signal has not dropped below the threshold.

20. The method of claim 11 further comprising determining whether an input signal has dropped below a threshold and scanning the block of audio data to generate the lookahead information if the input signal has dropped below the threshold.
